(19) United States
(12) Patent Application Publication
(10) Pub. No.: US 2026/0060130 A1
(43) Pub. Date: Feb. 26, 2026

(54) MICROELECTRONIC ASSEMBLIES

(71) Applicant: ADEIA SEMICONDUCTOR BONDING TECHNOLOGIES INC., San Jose, CA (US)

(72) Inventor: Belgacem Haba, Saratoga, CA (US)

(21) Appl. No.: 19/228,512

(22) Filed: Jun. 4, 2025

Related U.S. Application Data
(63) Continuation of application No. 18/733,052, filed on Jun. 4, 2024, now Pat. No. 12,341,025.
Application No. 18/733,052 is a continuation of application No. 17/937,593, filed on Oct. 3, 2022, now Pat. No. 12,046,482.
Application No. 17/937,593 is a continuation of application No. 16/503,021, filed on Jul. 3, 2019, now Pat. No. 11,462,419.
(60) Provisional application No. 62/694,543, filed on Jul. 6, 2018.

(51) Int. Cl. H01L 21/56; H01L 21/768; H01L 23/31; H01L 23/528; H10D 84/01

(52) U.S. Cl. CPC H01L 21/565; H01L 21/76819; H01L 21/76877; H01L 23/3107; H01L 23/528; H10D 84/01; H01L 2224/02379

(57) ABSTRACT

Various embodiments of fanout packages are disclosed. A method of forming a microelectronic assembly is disclosed. The method can include bonding a first surface of at least one microelectronic substrate to a surface of a carrier using a direct bonding technique without an intervening adhesive, the microelectronic substrate having a plurality of conductive interconnections on at least one surface of the microelectronic substrate. The method can include applying a molding material to an area of the surface of the carrier surrounding the microelectronic substrate to form a reconstituted substrate. The method can include processing the microelectronic substrate. The method can include singulating the reconstituted substrate at the area of the surface of the carrier and at the molding material to form the microelectronic assembly.

### CROSS-REFERENCE TO RELATED APPLICATIONS

This application is a continuation of U.S. patent application Ser. No. 18/733052, filed Jun. 4, 2024, which is a continuation of U.S. patent application Ser. No. 17/937593, filed Oct. 3, 2022, which is a continuation of U.S. patent application Ser. No. 16/503,021, filed Jul. 3, 2019, which claims priority to U.S. Provisional Ser. No. 62/694,543, filed on Jul. 6, 2018, the entire contents of which are incorporated by reference herein in their entirety and for all purposes.

### BACKGROUND

### Field of the Invention

The field relates to microelectronic assemblies and, in particular, to microelectronic assemblies comprising packages (e.g., fanout or fan-in packages) that include one or more components that are directly bonded to one another without an intervening adhesive.

### Description of the Related Art

In various packaging arrangements, singulated integrated device dies can be adhered with an adhesive onto a carrier such as tape or film. The singulated integrated device dies can be overmolded with a molding compound, forming what is sometimes referred to as a reconstituted wafer for further processing. Relatively fine-pitched electrical contacts of the one or more integrated device dies can be fanned out over the mold by a redistribution layer (RDL) to connect to relatively coarse-pitched electrodes or leads of another structure, such as a system substrate or motherboard. The dies can then be singulated from the reconstituted wafer, along with some of the side molding and overlying RDL. However, there remains a continuing need for improved packages and techniques for forming such packages.

### BRIEF DESCRIPTION OF THE DRAWINGS

These aspects and others will be apparent from the following description of preferred embodiments and the accompanying drawing, which is meant to illustrate and not to limit the invention, wherein:

FIG. 1A is a schematic side view of a carrier, according to various embodiments.

FIG. 1B is a schematic side view of a partially-formed microelectronic assembly including a plurality of elements directly bonded to the carrier without an intervening adhesive.

FIG. 1C is a schematic side view of a partially-formed microelectronic assembly in which a molding compound is applied around and between adjacent elements.

FIG. 1D is a schematic side view of a partially-formed microelectronic assembly in which a molding compound is applied around and between adjacent elements, and between adjacent interconnections on front surfaces of the elements.

FIG. 1E is a schematic side view of a partially-formed microelectronic assembly in which a redistribution layer (RDL) is applied over an upper surface of the molding compound and over front surfaces of the elements.

FIG. 1F is a schematic side view of a partially-formed microelectronic assembly after at least a portion of the carrier has been removed.

FIG. 1G is a schematic side view of a plurality of microelectronic assemblies after singulation.

FIG. 1H is a schematic side view of a plurality of microelectronic assemblies in which the carrier has been completely removed from the elements.

FIG. 1I is a schematic side view of a plurality of microelectronic assemblies including a plurality of through-mold vias.

FIG. 1J is a schematic side view illustrating a partially-formed microelectronic assembly that comprises a stacked structure.

FIG. 1K is a schematic side view illustrating a plurality of singulated microelectronic assemblies comprising stacked structures, according to various embodiments.

FIG. 2A is a schematic side view of a carrier, according to another embodiment.

FIG. 2B is a schematic side view of a partially-formed microelectronic assembly including a plurality of elements directly bonded to the carrier without an intervening adhesive.

FIG. 2C is a schematic side view showing a molding compound applied over and between the plurality of elements on the carrier.

FIG. 2D is a schematic side view of the partially-formed microelectronic assembly of FIG. 2C, after the molding compound and elements have been thinned by a thinning process.

FIG. 2E is a schematic side view of the partially-formed microelectronic assembly of FIG. 2D, after at least a portion of the carrier has been removed.

FIG. 2F is a schematic side view of the partially-formed microelectronic assembly that includes a redistribution layer (RDL) over front surfaces of the elements.

FIG. 2G is a schematic side view showing a plurality of singulated microelectronic assemblies, according to various embodiments.

FIG. 2H is a schematic side view of a plurality of microelectronic assemblies including a plurality of through-mold vias.

FIG. 3 is a schematic diagram of a system incorporating one or more microelectronic assemblies, according to various embodiments.

### DETAILED DESCRIPTION

Elements, including semiconductor elements such as integrated device dies (or “dies”) or wafers, may be stacked in a three-dimensional (3D) arrangement, arranged laterally relative to one another in a side-by-side arrangement, or otherwise packaged to connect to an external system as part of various microelectronic packaging schemes. This can include stacking a layer of one or more elements (e.g., one or more dies, devices, and/or wafers) on a larger carrier, such as a larger base die, device, or wafer, stacking multiple dies or wafers in a vertical or horizontal arrangement, and various combinations thereof. The elements can be provided with one or more redistribution layers (RDL). The RDL can provide greater spacing between pads than the pads on the dies, thus facilitating connections with other electronic components.

For instance, one or more elements (e.g., integrated device dies) may be stacked onto a carrier (e.g., wafer, substrate, etc.) to form a packaging arrangement to facilitate interconnecting the dies with other circuits, boards, packages, and so forth. The dies may be formed with finely-pitched and finely-spaced conductive interconnections (e.g., less than about 5 microns, for example, about 1 micron, etc.) that may be densely arranged and exposed on a surface of the dies. These finely-spaced interconnections may be intended to be electrically coupled to similarly finely-spaced interconnections of a redistribution layer (RDL), which are electrically continuous with a coarser set of interconnections (fanout) of the RDL, suitable for interconnection with the other circuits, boards, packages, and so forth. In many cases, the RDL may be formed as one or more metallization layers using a lithographic process, or the like. In some embodiments that include fanout packages, electrical contacts of the RDL can be coarser than contacts on the element (e.g., die) and can extend outside the footprint of the element (e.g., die). In other embodiments, the package can comprise a fan-in package, in which electrical contacts of the RDL may be disposed within the footprint of the element (e.g., die).

One method of providing RDL involves wafer-level packaging in which dies (e.g., integrated circuits) are singulated from wafer in which they are formed and then attached to the carrier using an adhesive or the like. An overmold may be applied to at least partially cover the carrier between the dies (and in some cases cover all or a portion of the exposed surfaces of the dies), to form a reconstituted substrate (which can comprise a reconstituted wafer or panel) that may be subjected to additional processing, such as the formation of RDL layer(s) for fanning out electrical connections. By spreading out over the adjacent molding, the RDL pads can be made bigger and/or with greater spacing than the pads on the dies. However, in some cases, the dies may shift position on the carrier during the overmolding process. In those cases, the adhesive may not hold the dies firmly in their placed positions when the overmold is applied. Even a small shift of the dies can result in the lithographic mask for the fanout metallization layer not matching or aligning with the fine pitch interconnects on the die. In some cases, the pitch of the die interconnects can be increased to account for the shift of the dies, however this can restrict the pitch (and the footprint of the die) to a size that is larger than desirable for many applications. Moreover, in some arrangements, the element or die tends to get pressed into the relatively soft adhesive. When the adhesive and carrier are removed (for example, by ultraviolet release), there may be a small step between the element (e.g., die) and the molding compound because the adhesive (now released) is higher than the die. Such a step creates issues for RDL formed over the previously covered surface, as the RDL dielectric must be thick enough to overcome the step and form reliable connections, which in turn creates high aspect ratio vias to be filled.

In an embodiment disclosed herein, the dies may be bonded to the carrier using various direct bonding techniques, including direct dielectric bonding, non-adhesive techniques, such as ZiBond® or a hybrid bonding technique, such as DBI®, both commercially available from Invensas Bonding Technologies, Inc. (formerly Ziptronix, Inc.), a subsidiary of Xperi Corp. The bonding includes a spontaneous process that takes place at ambient conditions when two prepared surfaces (such as the bonding surface of the dies and a prepared surface of the carrier) are brought together (see, for example, U.S. Pat. Nos. 6,864,585 and 7,485,968, which are incorporated by reference herein in their entirety). In some examples, respective mating surfaces of the bonded dies and the carrier can include the finely-spaced conductive interconnect structures of the dies, when the dies are bonded in a “face down” arrangement, for instance.

When bonding the dies to the carrier using a direct bonding or hybrid bonding technique, it is desirable that the surfaces of the dies to be bonded and the surface of the carrier be extremely flat and smooth. For instance, in general, the surfaces should have a very low variance in surface topology (i.e., nanometer scale variance, for example below 2 nm and preferably below 0.5 nm), so that the surfaces can be closely mated to form a lasting bond. Various conventional processes, such as chemical mechanical polishing (CMP) may be used to achieve the low surface roughness. It is also usually desirable that the surfaces be clean and have a low level of impurities, particles, or other residue that are large enough in size to cause bonding voids that can cause electrical continuity failures or other bonding defects.

In various embodiments disclosed herein, bonding the dies to the carrier using a direct bonding technique at ambient conditions and without an intervening adhesive (such as ZiBond® or DBI®, for example) allows the dies to be locked into position on the carrier and remain coplanar with one another. In this locked condition, the dies are not able to shift position during overmolding, or during any other process steps. Consequently, the lithographic mask for the fanout metallization layer has a high probability of matching and aligning with the fine pitch interconnects on the die, which can be formed to have as fine a pitch as desired for the intended application.

In various implementations, the dies can be processed while bonded to the carrier. For example, the processing can include the overmolding, the addition of the metallic fanout layer (e.g., RDL), and singulation with or without removal of the carrier. In some implementations, holes or openings (e.g., cavities) may be formed in the molding, which can be filled with metallic or other conductive materials to form through vias, contact pads, and so forth.

After processing, the carrier may be thinned, etched, or grinded away. In an implementation, the removal of the carrier can reveal metallic interconnects on the exposed die surface for RDL use (when the dies are bonded “face down,” for example). An additional routing layer can be added to the revealed metallic interconnects if desired. Added vias may also be revealed at the exposed surface of the die or the molding, with the removal of the carrier. In some implementations, a portion of the carrier may be allowed to remain bonded to the dies, to act as a heat sink, a handle, or a structural support. The dies may be separated by singulation, at the molded area outside the periphery of the dies, before or after removal of the carrier, to form the package arrangements desired.

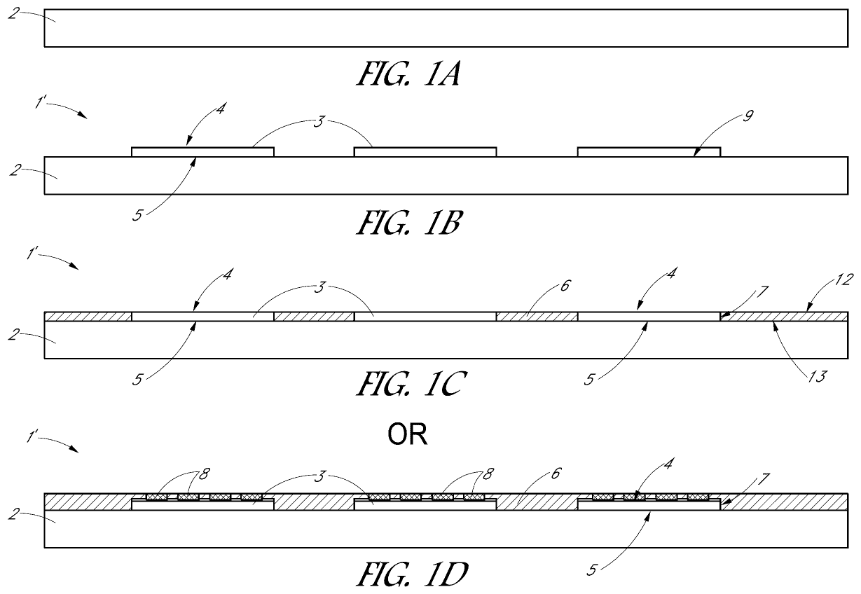

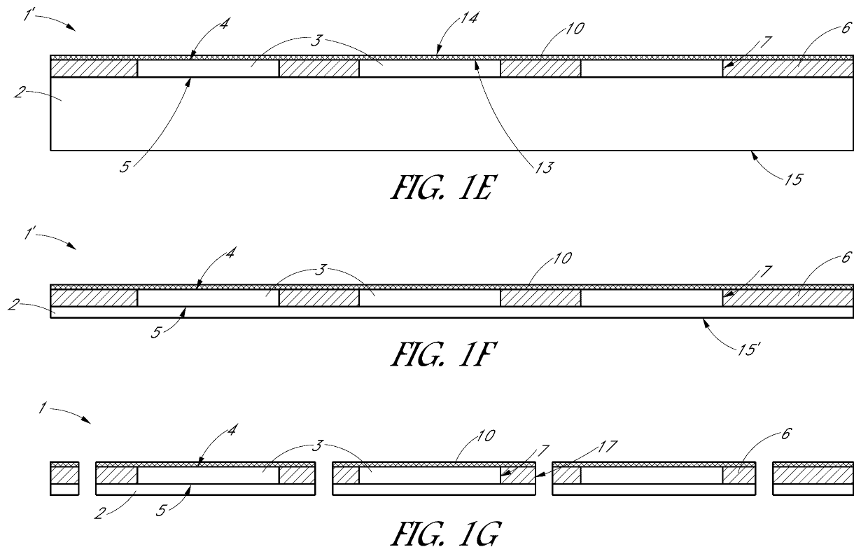

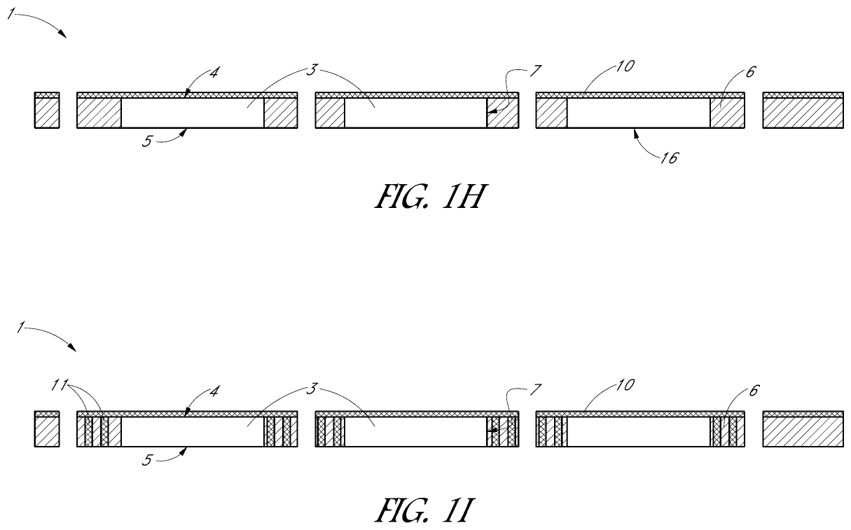

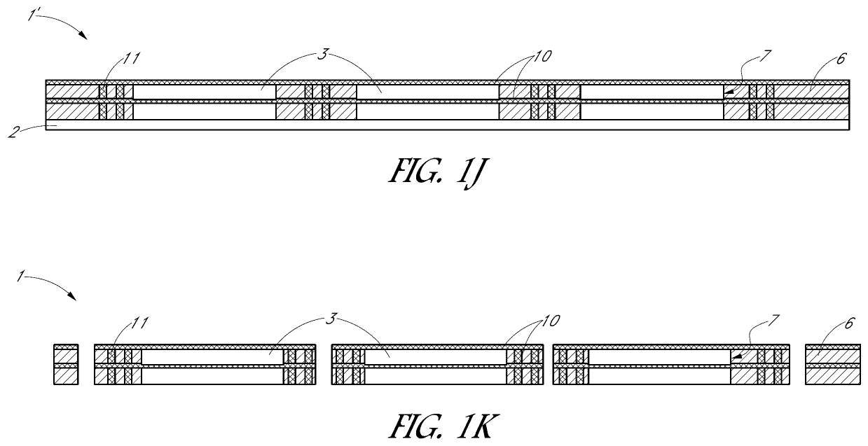

FIGS. 1A-1I illustrate a face-up method for forming a microelectronic assembly 1, according to various embodiments. FIG. 1A is a schematic side view of a carrier 2, according to various embodiments. The carrier 2 can comprise any suitable support structure on which the dies can be directly bonded, such as an integrated device die, an interposer, a package substrate, an electronic device, an optical device, a wafer, a glass substrate, a silicon on insulator (SOI) substrate, etc. The use of silicon, glass, or other semiconductor material for the carrier 2 can advantageously enable the carrier 2 to be polished to a very low surface roughness for directly bonded to other elements, such as integrated device dies. In other embodiments, however, the carrier 2 can comprise substrates of other materials (e.g., a ceramic substrate, a polymer substrate, or any other suitable substrate) on which a direct bonding layer of suitable material can be formed and polished. In some embodiments, the carrier 2 can comprise active electronic circuitry. In other embodiments, the carrier 2 may not include active circuitry.

FIG. 1B is a schematic side view of a partially-formed microelectronic assembly 1 including a plurality of elements 3 directly bonded to the carrier 2 without an intervening adhesive. The elements 3, can comprise, for example, thinned integrated device dies. The elements 3 can comprise any suitable type of element, such as an integrated device die, an optical device, etc. The element 3 can comprise a microelectronic substrate having one or more active devices formed therein or thereon. For example, each of the elements 3 can comprise a processor die, a memory die, a microelectromechanical systems (MEMS) die, a passive component, an optical device, or any other suitable type of device die. Circuitry (such as active components like transistors) can be patterned at or near active surfaces of the elements 3 in various embodiments. Although only three elements 3 are shown in FIG. 1B, it should be appreciated that more or fewer than three elements 3 may be mounted to the carrier 2. Further, in some embodiments, the elements 3 may be tested for appropriate electrical functionality before mounting the elements 3 to the carrier 2. In some embodiments, only known good dies (KGDs) may be selected for mounting to the carrier 2. In other embodiments, the dies may be tested for electrical functionality after being mounted to the carrier 2 or after forming RDL. The elements 3 of FIG. 1B comprise integrated device dies having various active (and/or passive) components. In other embodiments, one or more discrete passive devices may be mounted to the substrate without being formed as part of an integrated device die.

The elements 3 can be attached to the carrier 2 using any suitable direct bonding technique to directly bond to the carrier 2 without an intervening adhesive. As shown in FIG. 1B, for example, the element 3 can include a front surface 4 and a back surface 5 opposite the front surface 4. In the embodiment of FIG. 1B, the back surface 5 can be directly bonded to the carrier 2, such that the front surface 4 faces away from the carrier 2. In various embodiments, the front surface 4 of the elements 2 can comprise a plurality of conductive interconnections (e.g., metallic pads or traces) to provide electrical communication between the element 3 and other devices. Typically, active circuitry or devices are disposed at or near the front surface 4. In some embodiments, active circuitry or devices may also be disposed at or near the back surface 5, or between the front and back surfaces 4, 5. In FIG. 1B, non-conductive field regions at the back surfaces 5 of the elements 3 can directly contact and be directly bonded with corresponding non-conductive regions of the carrier 2.

To accomplish the direct bonding, in some embodiments, bonding surfaces of the elements 3 (e.g., the back surfaces 5) and the carrier 2 can be prepared for bonding. The elements 3 can be planarized and/or polished to a very high degree of smoothness (e.g., less than 20 nm surface roughness, or more particularly, less than 5 nm surface roughness, less than 2 nm surface roughness, or less than 0.5 nm surface roughness). In some embodiments, a bonding layer (e.g., a dielectric such as silicon oxide) may be deposited on the bonding sides, e.g., the back surfaces 5 of the elements 3 and/or on the front surface of the carrier 2, and polished to a very high degree of smoothness. In some embodiments, the bonding surfaces may be fluorinated to improve bonding. The bonding surfaces may also include conductive features, such as bond pads, in various arrangements. In some embodiments, the surfaces to be bonded may be terminated with a suitable species and activated prior to bonding. For example, in some embodiments, the surfaces to be bonded may be very lightly etched for activation and exposed to a nitrogen-containing solution and terminated with a nitrogen-containing species. As one example, the surfaces to be bonded may be exposed to an ammonia dip after a very slight etch, and/or a nitrogen-containing plasma (with or without a separate etch).

Once the surfaces are prepared, the nonconductive field regions at the back surfaces 5 of the elements 3 can be brought into contact with corresponding nonconductive regions of the carrier 2. The interaction of the activated surfaces can cause the nonconductive regions of the elements 3 to directly bond with the corresponding nonconductive regions of the carrier 2 without an intervening adhesive along a bonding interface 9, without application of external pressure, without application of voltage, and at room temperature. Such room temperature, atmospheric or reduced pressure bonding can result in bond strengths of about of at least 500 mJ/m², at least 1000 mJ/m², or at least 2000 mJ/m², for example, in a range of 500 mJ/m² to 2000 mJ/m². In various embodiments, the carrier 2 and elements 3 may be heated after bonding to strengthen the bonds between the nonconductive regions to cause the elements 3 to bond with the carrier 2. After annealing, the bond strength can increase to above 2000 mJ/m², for example, about 2500 mJ/m². Additional details of direct bonding processes may be found throughout U.S. Pat. Nos. 7,126,212; 8,153,505; 7,622,324; 7,602,070; 8,163,373; 8,389,378; 8,735,219; 9,953,941; and 10,204,893, the contents of each of which are hereby incorporated by reference herein in their entirety and for all purposes.

FIGS. 1C and 1D illustrate alternative methods for molding the partially-formed microelectronic assembly 1 of FIG. 1B. For example, FIG. 1C is a schematic side view of the partially-formed microelectronic assembly 1, in which an overmold or molding compound 6 is provided over a surface of the carrier 2 between and around the elements 3. A plate (not shown) can be provided over the front surfaces 4 of the elements 3, and the molding compound 6 can be flowed between the plate and the carrier 2, such that the molding compound 6 underfills spaces or gaps between adjacent elements 3 and under the plate. The molding compound 6 can accordingly be applied to an area of the exposed surface of the carrier 2 that surrounds the elements 3. Further, as shown, the molding compound 6 can be disposed along and can contact side surfaces 7 of the elements 3, which side surfaces 7 may be defined by bulk semiconductor material. The plate can ensure that the upper surface 12 of the molding compound 6 is generally co-planar or flush with the front surfaces 4 of the elements 3 (for example, within 1 μm, or within 0.25 μm), while direct bonding the elements 3 with the carrier 2 can ensure the back surface 5 are flush with the molding compound 6. For example, in various embodiments, the upper surface 12 of the molding compound 6 can be co-planar with the front surfaces 4 of the elements 3 within about 1 μm. Significantly, the back surface 13 of the mold compound 6 can be co-planar with the back surfaces of the elements 3 within about 1 μm, due to replacement of adhesive with direct bonding. In some embodiments, the co-planarity may be within about 0.05 μm to about 0.15 μm.

The molding compound 6 can comprise an organic filler material (such as an epoxy, a resin, etc.) that can have a flowable state in which the molding compound 6 flows between the elements 3. The molding compound 6 can be cured to form a hardened or cured state. In various embodiments, the molding compound can comprise an epoxy resin, for example, an epoxy resin with filler particles, such as silicon oxide filler particles. As explained above, in other processes in which the elements 3 are adhered to the carrier 2 with an adhesive, the overmolding process can cause the elements 3 to shift, which can cause misalignment when connecting pads to a fanout metallization layer. Beneficially, the embodiments disclosed herein can avoid such lateral shifts of the elements 3 during overmolding, because the direct bond between the elements 3 and the carrier 2 effectively lock the elements 3 in place laterally. Moreover, direct bonding advantageously obviates the use of an adhesive, which can prevent the step that results from the elements 3 sinking into the adhesive and loss of co-planarity, as explained above.

In a variant shown in FIG. 1D, conductive interconnections 8 (e.g., bond pads) can be provided on and can extend above the front surface 4 of the element 3. In FIG. 1D, a plate can be provided over the conductive interconnections 8, and the molding compound 6 can be flowed over the area of the surface of the carrier 2 surrounding the elements 3. As with FIG. 1C, in FIG. 1D, the molding compound 6 can extend along and contact the side surfaces 7 of the elements 3. Moreover, the molding compound 6 can flow between adjacent conductive interconnections 8 at the front surfaces 4 of the elements 3. As with FIG. 1C, the direct bonding of the elements 3 to the carrier 2 can prevent shifting of the elements 3 during overmolding and can prevent the formation of a step between the elements 3 and molding compound 6.

Turning to FIG. 1E, a redistribution layer (RDL) 10 can be provided over the upper surface 12 of the molding compound 6 and over the front surfaces 4 of the elements 3. The RDL 10 can comprise a first surface 13 having finely-spaced electrical interconnections (not shown) that are electrically coupled to the similarly finely-spaced conductive interconnections (such as interconnections 8) at the front surfaces 4 of the elements 3. The finely-spaced interconnections of the RDL 10 can be in electrical connection with a coarser set of interconnections (fanout) at a second surface 14 of the RDL 10. The coarser set of interconnections can be suitable for interconnection with the other circuits, boards, packages, and so forth. In many cases, the RDL 10 may be formed as one or more metallization layers using a lithographic process. In other embodiments, the RDL 10 can be part of a structure that is directly hybrid bonded to the front surfaces 4 of the elements 3 without an intervening adhesive. In various embodiments, the RDL 10 can electrically connect to other devices that are stacked on the element(s) 3. In some embodiments, adjacent elements 3 may remain adjacent to one another after singulation and in common connection to the RDL 10, in which case the RDL 10 can electrically interconnect adjacent elements 3, e.g., first and second microelectronic substrates.

The RDL 10 of FIG. 1E can accordingly enable the fanout of electrical signals from the finely-spaced interconnections at the front surfaces 4 of the elements 3 to coarser interconnections at the second surface 14 of the RDL 10. For example, the conductive interconnections (such as interconnections 8) at the front surfaces 4 of the elements 3 can be spaced by less than 20 μm, or less than 15 μm, or less than 5 μm, e.g., in a range of 1 μm to 20 μm. The coarser interconnections at the second surface 14 of the RDL 10 can have spacings in a range of 5 μm to 20 μm. Moreover, due to co-planarity provided by direct bonding, the RDL 10 can be made thinner than RDLs of other techniques. For example, the RDL 10 of the disclosed embodiments can include metal layers on or within dielectric layers of less than about 5 μm, such as 1-4 μm, or in some embodiments less than about 1 μm. Moreover, the RDL metal lines can have very fine pitch, such as about 10 μm using today's metallization technology for RDL, but can be finer for furture technologies given the precision afforded by direct bonding.

Turning to FIG. 1F, at least a portion of a backside 15 (see FIG. 1E) of the carrier 2 can be removed to form a planarized backside 15′ (see FIG. 1F). In the embodiment of FIG. 1F, only a portion of a thickness of the carrier 2 has been removed. The remaining portion of the carrier 2 can serve as at least one of a heat sink, a handle, or a structural support. In various embodiments, the at least a portion of the backside 15 can be removed by lapping, etching, polishing, or any other suitable removal technique. In other embodiments, the carrier 2 can be sacrificial such that the entire carrier 2 can be removed from the molding compound 6 and the elements 3. In embodiments in which the entire carrier 2 is removed, a bonding layer of the elements 3 (such as a silicon oxide layer) and/or the molding compound 6 can serve as a stop (e.g., an etch stop, etc.) for the removal process. In either case, the at least partial removal of the carrier 2 can result in a planar backside (e.g., planarized backside 15′ of the carrier 2 or planar bonding surface of the element 3 together with the back surface of the molding compound 6) of the microelectronic assembly 1. The planar backside of the microelectronic assembly 1 can be directly bonded to other devices or elements without an intervening adhesive.

In FIG. 1G, the microelectronic assembly 1′ can be singulated through the carrier 2 and the molding compound 6 to form a plurality of microelectronic assemblies 1. For example, the microelectronic assembly 1′ can be singulated by sawing through the carrier 2 and the molding compound 6, or just through the molding compound 6 if the carrier was fully removed. After singulation, the molding compound 6 and the RDL 10 can include one or more singulated side surfaces 17 that include markings indicative of a singulation process. For example, the singulated side surfaces 17 can include saw markings. It should be appreciated that although each singulated microelectronic assembly 1 of FIG. 1G includes a single element 3, in other arrangements, the assembly 1 can include a plurality of elements 3 to form a system-in-package. For example, the assembly 1 can include a plurality of elements 3 stacked on one another and/or disposed laterally adjacent to one another.

FIG. 1H illustrates an arrangement in which the carrier 2 has been completely removed from the molding compound 6 and the elements 3. In some embodiments, a majority of the carrier 2 can be removed, except for a bonding layer that may include conductive interconnects embedded in a nonconductive or dielectric region. The carrier 2 can be removed prior to singulation, e.g., prior to the step shown in FIG. 1G. In other embodiments, the carrier 2 can be removed after singulation. In FIG. 1H, each singulated microelectronic assembly 1 can be connected to other structures. For example, each microelectronic assembly 1 can electrically connect to other structures at top or bottom surfaces of the assembly 1. For example, the RDL 10 at upper surfaces of the microelectronic assembly 1 can be electrically connected (e.g., wire bonded, flip chipped, directly hybrid bonded) to other structures, such as other packages, other carriers, other device dies, etc. See, for example, FIG. 1J, described in more detail below.

Moreover, the back surfaces 5 of the elements 3 can be electrically connected (e.g., directly bonded) to other structures as well. In such arrangements, back surfaces 5 of the elements 3 can be electrically connected (e.g., directly bonded) to other structures, such as other packages, other dies, other carriers, etc. For example, in various embodiments, singulated packages or microelectronic assemblies 1 can comprise a plurality of elements (e.g., dies) that are electrically connected to one another by way of conductive traces and contacks of the RDL 10. In some embodiments, the back surfaces 5 can include a bonding layer including a nonconductive field region with conductive interconnects defined therein or thereon. The bonding layer (e.g., the nonconductive field region and the conductive interconnects) can be directly bonded to corresponding nonconductive field regions and conductive interconnects of other structures without an intervening adhesive. In various embodiments, for example, the bonding layer can be provided at the back surfaces 5 of the elements 3 by deposing the bonding layer at the back surfaces 5. In other embodiments, the bonding layer of the carrier 2 (which can include nonconductive field regions and conductive contacts) can remain after the at least a portion of the carrier 2 is removed. In such an arrangement, the remaining bonding layer of the carrier 2 can serve to electrically connect to other structures. In still other embodiments in which a portion of the carrier 2 remains connected to the elements 3 and the molding compound 6, the carrier 2 can serve as an interposer to connect to the other structures.

FIG. 1I is a schematic side view of a plurality of microelectronic assemblies 1 including vias 11 that extend from the RDL 10 through the molding compound 6 to the back surface of the molding compound 6. Thus the illustrated vias 11 can be referred to as through-mold vias. To form the vias 11, one or more cavities can be formed (e.g., etched), and a conductive material can be provided in the cavities to form the conductive vias 11. The vias 11 can provide electrical communication between the RDL 10 and other structures (not shown) which may electrically connect to the back side of the molding compound 6 and elements 3. The vias 11 can be formed at the same time as the RDL layer 10 shown in FIG. 1E. Beneficially, the use of the through-mold vias 11 can be less costly and complicated to manufacture than through-substrate vias, e.g., vias that pass through elements 3. In some embodiments, the elements 3 may not include through-substrate vias. In other embodiments, the elements 3 may include through-substrate vias.

For example, as shown in FIG. 1J, the microelectronic assembly 1′ can include a plurality of elements 3 stacked on top of one another. In the embodiment of FIG. 1J, for example, the elements 3 can be stacked prior to singulation. Additional elements 3 can be stacked on the lower layer of elements 3 and directly bonded to the RDL 10. Molding compound can be applied between adjacent elements 3 as explained above, and RDL 10 can be provide over the stacked structure. In various embodiments, the adjacent molding compounds can be bonded with any suitable technique, such as, thermocompression bonding, direct bonding without an adhesive, etc. In various embodiments in which the molding compound 6 is direct bonded to vertically adjacent molding compound, a bonding layer (such as a silicon oxide bonding layer) can be applied between adjacent portions of the molding compound 6.

In another embodiment, two reconstituted wafers can each be formed, including RDL formation, and direct hybrid bonded to one another. Any suitable number of elements 3 can be stacked on top of one another. The assembly 1′ can be subsequently singulated into a plurality of singulated microelectronic assemblies 1 as shown in FIG. 1K. Moreover, as explained above, the carrier 2 can be completely removed in some embodiments, such as that shown in FIG. 1K. In other embodiments, at least a portion of the carrier 2 can remain bonded to the lower layer of elements 3. Although FIG. 1J illustrates stacked elements 3, in other embodiments, the elements 3 may not be stacked. For example, in other embodiments, the singulated assembly 1 may include laterally-spaced elements 3 after singulation, or only one element 3.

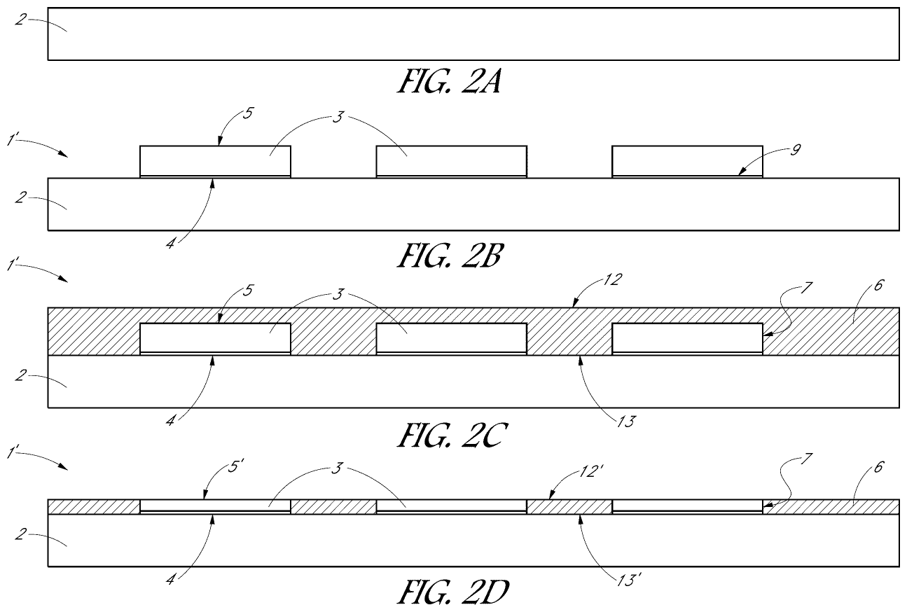

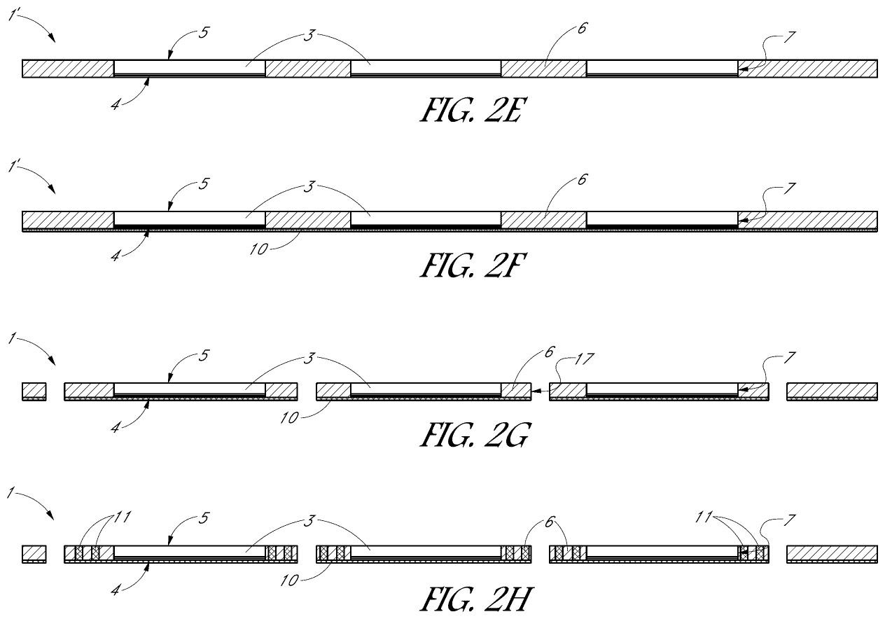

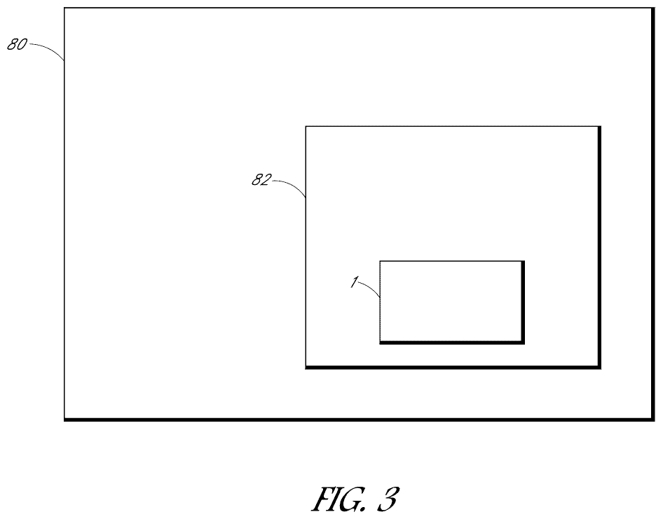

FIGS. 2A-2H illustrate a face-down method for forming a microelectronic assembly 1, according to various embodiments. Unless otherwise noted, the components of FIGS. 2A-2H may be the same as or generally similar to like-numbered components of FIGS. 1A-1I. For example, as with FIG. 1A, the carrier 2 can be provided in FIG. 2A. The carrier 2 can provide any suitable carrier, as explained above. In FIG. 2B, a plurality of elements 3 can be directly bonded to the carrier 2. However, unlike the embodiment of FIG. 1B, in FIG. 2B, the front surfaces 4 of the elements 3 can be directly bonded to the carrier 2 without an intervening adhesive. As explained above, the front surfaces 4 of the elements 3 can include conductive interconnections (not shown in FIG. 2B) embedded within or surrounded by a nonconductive field region. The conductive interconnections and nonconductive field region can be directly hybrid bonded to corresponding conductive interconnections and nonconductive field region of the carrier 2 along the bonding interface 9. Thus, in FIG. 2B, the front surfaces 4 of the elements 3 can face and be directly bonded to the carrier 2, and the back surfaces 5 can face away from the carrier 2.

Turning to FIG. 2C, the molding compound 6 can be applied over the elements 3 and areas of the surface of the carrier 2 between adjacent elements 3. As above, the molding compound 6 can be disposed along an upper surface of the carrier 2 and along side surfaces 7 of the elements 3. The molding compound 6 can comprise a filler material, such as a curable epoxy in various embodiments. Beneficially as explained above, the use of direct bonding to mount the elements 3 to the carrier 2 can prevent the elements from laterally shifting during overmold and can facilitate coplanarity of the molding compound with element surfaces.

In FIG. 2D, the elements 3 and molding compound 6 can be thinned during a thinning process. For example, in various embodiments, the back surfaces 5 of the elements 3 and the upper surface 12 of the molding compound 6 can be lapped, grinded, or otherwise thinned to form thinned back surfaces 5′ of the elements 3 and thinned upper surfaces 12′ of the molding compound 6. As with the embodiment of FIGS. 1A-1K, the back surfaces 5′ of the elements 3 can be substantially co-planar with the upper surfaces 12′ of the molding compound 6, while direct bonding also facilitates co-planarity between the lower surfaces 13′ of the molding compound 6 and the front surfaces 4 of the elements 3. Co-planarity can be, for example, within about 1 μm, for example, within about 0.1 μm.

Turning to FIG. 2E, at least a portion of the carrier 2 can be removed from the front surfaces 4 of the elements 3 and the lower surface of the molding compound 6. In some embodiments, the carrier 2 can be completely removed, e.g., removed except for a native oxide layer at the upper surface of the carrier 2). In some embodiments, for example, the carrier 2 can be removed by etching. In such arrangements, the native oxide layer can serve as a stop (e.g., an etch stop) for the removal process. The remaining native oxide layer may be less than 5 nm thick, e.g., 2 nm or less. In other embodiments, in which the carrier 2 includes a relatively thick bonding layer (such as an oxide layer), the majority of the carrier 2 (e.g., the silicon substrate) can be removed while leaving the bonding layer bonded to the elements 3 and the molding compound 6. In such an arrangement, the bonding layer can include contacts or traces within an oxide layer (or other dielectric layer) to serve as a routing layer, which can connect to structures below the front surfaces 4 of the elements 3. Once the at least a portion of the carrier 2 has been removed, the exposed front surfaces 4 can be planar, e.g., having a surface roughness of less than about 1 micron. Moreover, the front surfaces of the elements 3 can be generally co-planar with the exposed lower surface 13′ of the molding compound 6, as noted above.

In FIG. 2F, the RDL 10 can be provided over the front surfaces 4 of the elements 3 and over the lower surface 13′ of the molding compound 6. The RDL 10 may be generally similar to the RDL 10 described above in connection with FIGS. 1A-1K, and can provide a fanout electrical connection from relatively fine pitches of contacts on the elements 3 to relatively coarse pitches of contacts on a lower surface of the RDL 10, as described above. In FIG. 2G, the partially-formed microelectronic assembly 1′ of FIG. 2F can be singulated into a plurality of microelectronic assemblies 1, in a manner similar to that explained above in connection with FIGS. 1A-1K. For example, the molding compound 6 and the RDL 10 can include side surface(s) 17 having markings indicative of a singulation process, such as saw markings. Further, as shown in FIG. 2H, in some embodiments, a plurality of through-mold vias 11 can be provided to provide electrical communication through the molding compound 6. The microelectronic assembly 1 of FIGS. 21-2J can be stacked or arranged in any other suitable combination, as explained above with respect to FIGS. 1A-1K.

FIG. 3 is a schematic diagram of a system 80 incorporating one or more microelectronic assemblies 1, according to various embodiments. The system 80 can comprise any suitable type of electronic device, such as a mobile electronic device (e.g., a smartphone, a tablet computing device, a laptop computer, etc.), a desktop computer, an automobile or components thereof, a stereo system, a medical device, a camera, or any other suitable type of system. In some embodiments, the electronic device can comprise a microprocessor, a graphics processor, an electronic recording device, or digital memory. The system 80 can include one or more device packages 82 which are mechanically and electrically connected to the system 80, e.g., by way of one or more motherboards. Each package 82 can comprise one or more microelectronic assemblies 1. The microelectronic assemblies 1 shown in FIG. 3 can comprise any of the microelectronic assemblies 1 shown and described above in connection with FIGS. 1A-2H. The microelectronic assembly 1 can include one or more integrated device dies which perform various functions for the system 80.

In one embodiment, a method of forming a microelectronic assembly is disclosed. The method can include bonding a first surface of at least one microelectronic substrate to a surface of a carrier using a direct bonding technique without an intervening adhesive, the microelectronic substrate having a plurality of conductive interconnections on at least one surface of the microelectronic substrate. The method can include applying a molding material to an area of the surface of the carrier surrounding the microelectronic substrate to form a reconstituted substrate. The method can include processing the microelectronic substrate. The method can include singulating the reconstituted substrate at the area of the surface of the carrier and at the molding material to form the microelectronic assembly.

In another embodiment, a microelectronic assembly is disclosed. The microelectronic assembly can include an element having a front surface and a back surface opposite the front surface, at least one of the front and back surfaces comprising a planarized direct bonding surface. The microelectronic assembly can include a molding compound disposed around the element, the molding compound disposed along a side surface of the element, the molding compound including a first surface and a second surface opposite the first surface. The microelectronic assembly can include a redistribution layer (RDL) disposed over and electrically connected to the front surface of the element. The first surface of the molding compound can be substantially co-planar with the planarized direct bonding surface.

In another embodiment, a method of forming a microelectronic assembly is disclosed. The method can include directly bonding a first surface of an element to a carrier without an intervening adhesive, the element having a plurality of exposed conductive interconnections on at least one surface of the element. The method can include applying a molding compound around the element and along a side edge of the element. The method can include providing a redistribution layer (RDL) over and electrically connected to the at least one surface of the element. The method can include singulating through the RDL and the molding compound to form the microelectronic assembly.

For purposes of summarizing the disclosed embodiments and the advantages achieved over the prior art, certain objects and advantages have been described herein. Of course, it is to be understood that not necessarily all such objects or advantages may be achieved in accordance with any particular embodiment. Thus, for example, those skilled in the art will recognize that the disclosed implementations may be embodied or carried out in a manner that achieves or optimizes one advantage or group of advantages as taught or suggested herein without necessarily achieving other objects or advantages as may be taught or suggested herein.

All of these embodiments are intended to be within the scope of this disclosure. These and other embodiments will become readily apparent to those skilled in the art from the following detailed description of the embodiments having reference to the attached figures, the claims not being limited to any particular embodiment(s) disclosed. Although this certain embodiments and examples have been disclosed herein, it will be understood by those skilled in the art that the disclosed implementations extend beyond the specifically disclosed embodiments to other alternative embodiments and/or uses and obvious modifications and equivalents thereof. In addition, while several variations have been shown and described in detail, other modifications will be readily apparent to those of skill in the art based upon this disclosure. It is also contemplated that various combinations or sub-combinations of the specific features and aspects of the embodiments may be made and still fall within the scope. It should be understood that various features and aspects of the disclosed embodiments can be combined with, or substituted for, one another in order to form varying modes of the disclosed implementations. Thus, it is intended that the scope of the subject matter herein disclosed should not be limited by the particular disclosed embodiments described above, but should be determined only by a fair reading of the claims that follow.

1. (canceled)

2. A bonded structure, comprising:
a first die comprising an optical device, wherein the first die comprises a first surface that comprises a first region and a second region that is laterally adjacent to the first region, wherein the first region comprises a first nonconductive field region and a plurality of first conductive interconnections;
an electronic integrated circuit die having a second surface that comprises a second nonconductive field region and a plurality of second conductive interconnections, wherein the first die and the electronic integrated circuit die are hybrid bonded together such that the plurality of first conductive interconnections are directly bonded to the plurality of second interconnections and the first nonconductive field region is directly bonded to the second nonconductive field region and wherein the electronic integrated circuit die does not cover the second region; and
an insulating material over the second region.

3. The bonded structure of claim 2, wherein the electronic integrated circuit die comprises a side surface and wherein the insulating material directly contacts the side surface.

4. The bonded structure of claim 2, wherein the insulating material comprises silicon oxide.

5. The bonded structure of claim 2, wherein the electronic integrated circuit die comprises a back surface, wherein the insulating material comprises an upper surface, and wherein the upper surface and the back surface are substantially co-planar.

6. The bonded structure of claim 2, wherein the electronic integrated circuit die comprises a back surface and wherein the insulating material at least partially covers the back surface.

7. The bonded structure of claim 2, wherein the first die comprises a first side surface, the insulating material comprises a second side surface, and wherein the first and second side surfaces are coplanar with each other.

8. The bonded structure of claim 7, wherein the electronic integrated circuit die comprises a third side surface and wherein the insulating material extends between the third side surface and the second side surface.

9. The bonded structure of claim 7, wherein the first and second side surfaces at least partially define an outer surface of the bonded structure.

10. The bonded structure of claim 2, wherein the first die comprises first active circuitry electrically coupled to the plurality of first conductive interconnections, wherein the electronic integrated circuit die comprises second active circuitry electrically coupled to the plurality of second conductive interconnections, and wherein the first active circuitry and the second active circuitry are electrically coupled together with the pluralities of first and second conductive interconnections.

11. A method of forming a bonded structure, comprising:
providing a substrate that comprises an optical device, wherein the substrate comprises a first surface that comprises a first region and a second region that is laterally adjacent to the first region, wherein the first region comprises a first nonconductive field region and a plurality of first conductive interconnections;
providing an electronic integrated circuit die having a second surface that comprises a second nonconductive field region and a plurality of second conductive interconnections;
hybrid bonding the second surface to the first surface such that the plurality of first conductive interconnections are directly bonded to the plurality of second conductive interconnections and the first nonconductive field region is directly bonded to the second nonconductive field region, wherein the electronic integrated circuit die does not cover the second region; and
forming an insulating material over the second region.

12. The method of claim 11, wherein the electronic integrated circuit die comprises a side surface and wherein forming the insulating material over the second region comprises forming the insulating material such that it directly contacts the side surface.

13. The method of claim 11, wherein the insulating material comprises silicon oxide.

14. The method of claim 11, wherein the electronic integrated circuit die comprises a back surface, wherein the insulating material comprises an upper surface, and wherein forming the insulating material over the second region comprises forming the insulating material such that the upper surface and the back surface are substantially co-planar.

15. The method of claim 11, wherein the electronic integrated circuit die comprises a back surface and wherein forming the insulating material over the second region comprises:
depositing the insulating material over the electronic integrated circuit die and over the second region such that the insulating material at least partially covers the back surface.

16. The method of claim 15, further comprising:
thinning the insulating material such that the insulating material is substantially co-planar with the back surface of the electronic integrated circuit die.

17. The method of claim 15, further comprising:
simultaneously thinning the insulating material and the electronic integrated circuit die such that the insulating material is substantially co-planar with a post-thinning surface of the electronic integrated circuit die.

18. The method of claim 11, wherein the optical device comprises a first side surface, the insulating material comprises a second side surface, and wherein the first and second side surfaces are coplanar with each other.

19. The method of claim 18, wherein the electronic integrated circuit die comprises a third side surface and wherein the insulating material extends between the third side surface and the second side surface.

20. The method of claim 18, wherein the first and second side surfaces at least partially define an outer surface of the bonded structure.

21. The method of claim 11, wherein the optical device comprises first active circuitry electrically coupled to the plurality of first conductive interconnections, wherein the electronic integrated circuit die comprises second active circuitry electrically coupled to the plurality of second conductive interconnections, and wherein the first active circuitry and the second active circuitry are electrically coupled together with the pluralities of first and second conductive interconnections.

22. A method of forming a bonded structure, comprising:
attaching a first surface of an electronic integrated circuit die to a carrier;
applying an insulating material over a second surface of the electronic integrated circuit die and adjacent a side edge of the electronic integrated circuit die;
after applying the insulating material, simultaneously thinning the electronic integrated circuit die and the insulating material to form a thinned electronic integrated circuit die having a post-thinning surface opposite the first surface;
after the thinning, providing an interconnection layer over the insulating material and the post-thinning surface of the thinned electronic integrated circuit die;
hybrid bonding a second element to the interconnection layer without an intervening adhesive;
removing the carrier from the thinned electronic integrated circuit die; and
singulating through the interconnection layer and the insulating material to form the bonded structure.

23. The method of claim 22, wherein attaching the first surface of the electronic integrated circuit die to the carrier comprises directly bonding the first surface of the electronic integrated circuit die to the carrier such that a non-conductive field region of the first surface is directly bonded to the carrier without an intervening adhesive.

24. The method of claim 22, wherein attaching the first surface of the electronic integrated circuit die to the carrier comprises bonding an active side of the electronic integrated circuit die to the carrier.

25. The method of claim 22, further comprising applying a second insulating material over the interconnection layer laterally adjacent the second element.

26. The method of claim 25, wherein singulating comprises singulating through the second insulating material.

27. The method of claim 22, wherein attaching the first surface of the electronic integrated circuit die to the carrier comprises attaching a known good die (KGD) to the carrier.

28. The method of claim 22, wherein, after thinning the electronic integrated circuit die and the insulating material, a surface of the insulating material is co-planar with the post-thinning surface.
